(19) United States
(12) Patent Application Publication
(10) Pub. No.: US 2023/0340266 A1
(43) Pub. Date: Oct. 26, 2023

(54) SILICON-CONTAINING COMPOSITION AND METHOD FOR MANUFACTURING SEMICONDUCTOR SUBSTRATE

(71) Applicant: JSR CORPORATION, Tokyo (JP)

(72) Inventors: Tomoaki SEKO, Tokyo (JP); Yusuke ANNO, Tokyo (JP); Akitaka NII, Tokyo (JP); Ryuichi NEMOTO, Tokyo (JP); Souta NISHIMURA, Tokyo (JP)

(73) Assignee: JSR CORPORATION, Tokyo (JP)

(21) Appl. No.: 18/198,954

(22) Filed: May 18, 2023

Related U.S. Application Data
(63) Continuation of application No. PCT/JP2021/041734, filed on Nov. 12, 2021.

(30) Foreign Application Priority Data
Nov. 26, 2020 (JP) 2020-195942

(51) Int. Cl. G03F 7/32; C08L 83/04; G03F 7/11; G03F 7/20

(52) U.S. Cl. CPC C08L 83/04; G03F 7/11; G03F 7/322; G03F 7/70025; G03F 7/70033; C08L 2203/20

(57) ABSTRACT

A silicon-containing composition includes: a polysiloxane including a first structural unit represented by formula (1); and a solvent. X is an alkali-dissociable group; a is an integer of 1 to 3; and when a is 2 or more, a plurality of Xs are the same or different from each other. R¹ is a monovalent organic group having 1 to 20 carbon atoms, a hydroxy group, or a halogen atom; b is an integer of 0 to 2; and when b is 2, two R¹s are the same or different from each other. a + b is 3 or less.

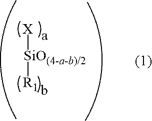

### CROSS REFERENCE TO RELATED APPLICATIONS

The present application is a continuation-in-part application of International Patent Application No. PCT/JP2021/041734 filed Nov. 12, 2021, which claims priority to Japanese Patent Application No. 2020-195942 filed Nov. 26, 2020. The contents of these applications are incorporated herein by reference in their entirety.

### BACKGROUND OF THE DISCLOSURE

### Technical Field

The present disclosure relates to a silicon-containing composition and a method for manufacturing a semiconductor substrate.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2012/0393337).

### SUMMARY OF THE DISCLOSURE

According to an aspect of the present disclosure, a silicon-containing composition includes: a polysiloxane including a first structural unit represented by formula (1); and a solvent. X is an alkali-dissociable group; a is an integer of 1 to 3; and when a is 2 or more, a plurality of Xs are the same or different from each other. R¹ is a monovalent organic group having 1 to 20 carbon atoms, a hydroxy group, or a halogen atom; b is an integer of 0 to 2; and when b is 2, two R¹_{S} are the same or different from each other. a + b is 3 or less.

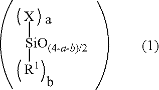

According to another aspect of the present disclosure, a method for manufacturing a semiconductor substrate, including directly or indirectly applying the above-described silicon-containing composition to a substrate to form a silicon-containing film. A composition for forming a resist film is directly or indirectly applied to the silicon-containing film to form a resist film. The resist film is exposed to radiation. The exposed resist film is developed to form a resist pattern.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4 - 7.2 as does the following list of values: 1, 4, 6, 10.

An embodiment of the present disclosure relates to a silicon-containing composition containing
a polysiloxane having a first structural unit represented by the formula (1) and
a solvent:

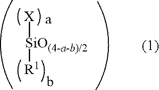

wherein X is an alkali-dissociable group, a is an integer of 1 to 3, when a is 2 or more, a plurality of Xs are the same or different from each other, R¹ is a monovalent organic group having 1 to 20 carbon atoms, a hydroxy group, or a halogen atom, b is an integer of 0 to 2, when b is 2, two R¹_{S} are the same or different from each other, and a + b is 3 or less.

The silicon-containing composition contains a polysiloxane having an alkali-dissociable group in the first structural unit. Therefore, when a silicon-containing film is formed from the silicon-containing composition, a resist pattern having excellent cross-sectional shape rectangularity can be formed (hereinafter, the cross-sectional shape rectangularity of the resist pattern is also referred to as “pattern rectangularity”). The reason for this is not clear, but can be expected as follows. When an exposed resist film is subjected to alkali development, the alkali-dissociable group of the polysiloxane is dissociated in an exposed portion so that the polarity of the polysiloxane increases and affinity or permeability of a developer for or into the silicon-containing film also increases. As a result, generation of a residue of the resist film near the interface between the resist film and the silicon-containing film is prevented so that excellent pattern rectangularity is achieved. On the other hand, in an unexposed portion, hydrophobicity of the silicon-containing film is maintained so that adhesion to the upper resist film is maintained. As a result, collapse of the resist pattern is prevented so that excellent pattern rectangularity is exhibited. As described above, it is expected that by forming a silicon-containing film from the silicon-containing composition, excellent pattern rectangularity can be exhibited due to a synergistic effect of prevention of generation of a residue in an exposed portion and prevention of pattern collapse in an unexposed portion.

As used herein, “polysiloxane” means a compound containing a siloxane bond (—Si—O—Si—). As used herein, “alkali-dissociable group” is a group containing a group that substitutes the hydrogen atom of a carboxy group or an alcoholic hydroxy group, and means a group containing a group that dissociates in a 2.38% by mass aqueous tetramethylammonium hydroxide solution under conditions of 23° C. and 1 minute. As used herein, “organic group” means a group containing at least one carbon atom, and “carbon number” means the number of carbon atoms constituting a group.

Another embodiment of the present disclosure relates to a method for manufacturing a semiconductor substrate, including
directly or indirectly applying the silicon-containing composition according to claim 1 to a substrate to form a silicon-containing film;
directly or indirectly applying a composition for forming a resist film to the silicon-containing film to form the resist film; and
exposing the resist film to radiation;
developing the exposed resist film to form a resist pattern.

In the manufacturing method, the silicon-containing composition is used to form the silicon-containing film as the underlayer of the resist film, and a resist pattern having an excellent rectangular cross-sectional shape can be formed, therefore, high-quality semiconductor substrates can be efficiently manufactured.

Hereinafter, a silicon-containing composition and a method for manufacturing a semiconductor substrate according to embodiments of the present disclosure will be described in detail.

### Silicon-Containing Composition

The silicon-containing composition according to the present embodiment contains a polysiloxane having an alkali-dissociable group and a solvent. The composition may contain other optional components (hereinafter also simply referred to as “optional components”) within a range that does not impair the effects of the present invention.

Since the silicon-containing composition contains the polysiloxane described above and a solvent, a resist pattern having excellent cross-sectional shape rectangularity can be formed when a resist pattern is formed on a silicon-containing film by alkali development. Since exhibiting the effect described above, the silicon-containing composition can suitably be used as a composition for forming a silicon-containing film (that is, a silicon-containing film forming composition).

The silicon-containing composition is suitably used for forming an underlayer film of an alkali-developable resist film. In this case, after the resist film is formed and exposed, an exposed portion of the resist film is dissolved during alkali development so that a silicon-containing film, which is the underlayer film of the resist film, is exposed. The silicon-containing film has improved affinity for a developer due to dissociation of the alkali-dissociable group by alkali development. This induces sufficient dissolution of the resist film near the interface between the resist film and the silicon-containing film, which makes it possible to form a resist pattern having excellent cross-sectional shape rectangularity. On the other hand, in an unexposed portion, hydrophobicity of the silicon-containing film is maintained so that adhesion between the resist film and the silicon-containing film is maintained. This makes it possible to prevent collapse of the resist pattern, which eventually contributes to improved pattern rectangularity.

As the resist film to be alkali-developed, a positive resist film is preferable, and a positive resist film for exposure with ArF excimer laser light (ArF exposure) or extreme ultraviolet (EUV) (EUV exposure) is more preferable. In other words, the silicon-containing composition is suitably used for forming an underlayer film of an alkali-developable resist film for ArF exposure or EUV exposure.

### [Polysiloxane]

The silicon-containing composition contains a polysiloxane having a predetermined first structural unit. The silicon-containing composition can contain one or more polysiloxanes. The polysiloxane may have structural units other than the first structural unit (hereinafter also simply referred to as “other structural units”) within a range that does not impair the effects of the present invention. Each of the structural units of the polysiloxane will be described below.

### (First Structural Unit)

The first structural unit is represented by the formula (1). The polysiloxane can have one or more first structural units. The first structural unit has an alkali-dissociable group represented by X in the formula (1), which makes it possible to form a silicon-containing film that can impart excellent pattern rectangularity to a resist pattern.

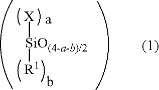

wherein X is an alkali-dissociable group, a is an integer of 1 to 3, when a is 2 or more, a plurality of Xs are the same or different from each other, R¹ is a monovalent organic group having 1 to 20 carbon atoms, a hydroxy group, or a halogen atom, b is an integer of 0 to 2, when b is 2, two R¹_{S} are the same or different from each other, and a + b is 3 or less.

The alkali-dissociable group represented by X in the formula (1) is not particularly limited as long as it is dissociated by an alkali, but may be a group obtained by incorporating an ester bond between two carbon atoms in a monovalent organic group having 1 to 30 carbon atoms.

Examples of the monovalent organic group having 1 to 30 carbon atoms in the alkali-dissociable group represented by X in the formula (1) include a monovalent hydrocarbon group having 1 to 30 carbon atoms, a group containing a divalent heteroatom-containing liking group between carbon-carbon bonds of the hydrocarbon group (hereinafter, also referred to as a “group (α)”), a group obtained by substituting a part or all of hydrogen atoms of the hydrocarbon group or the group (α) with a monovalent heteroatom-containing substituent (hereinafter, also referred to as a “group (β)”), and a group obtained by combining the hydrocarbon group, the group (α) or the group (β) with a divalent heteroatom-containing linking group (hereinafter, also referred to as a “group (γ)”).

As used herein, the “hydrocarbon group” includes a chain hydrocarbon group, an alicyclic hydrocarbon group, and an aromatic hydrocarbon group. The “hydrocarbon group” may be a saturated hydrocarbon group or an unsaturated hydrocarbon group. The “chain hydrocarbon group” means a hydrocarbon group that does not include a cyclic structure and is composed only of a chain structure, and includes both a linear hydrocarbon group and a branched hydrocarbon group. The “alicyclic hydrocarbon group” means a hydrocarbon group that includes only an alicyclic structure as a ring structure and does not include an aromatic ring structure, and includes both a monocyclic alicyclic hydrocarbon group and a polycyclic alicyclic hydrocarbon group. However, it is not necessary for the alicyclic hydrocarbon group to be composed only of an alicyclic structure, and the alicyclic hydrocarbon group may include a chain structure in a part thereof. The “aromatic hydrocarbon group” means a hydrocarbon group that includes an aromatic ring structure as a ring structure. However, it is not necessary for the aromatic hydrocarbon group to be composed only of an aromatic ring structure, and the aromatic hydrocarbon group may include a chain structure or an alicyclic structure in a part thereof.

Examples of monovalent hydrocarbon groups having 1 to 30 carbon atoms include monovalent chain hydrocarbon groups having 1 to 30 carbon atoms, monovalent alicyclic hydrocarbon groups having 3 to 30 carbon atoms, and monovalent aromatic hydrocarbon groups having 6 to 30 carbon atoms.

Examples of monovalent chain hydrocarbon groups having 1 to 30 carbon atoms include alkyl groups such as a methyl group, an ethyl group, a n-propyl group, an i-propyl group, a n-butyl group, a sec-butyl group, an iso-butyl group, a tert-butyl group, alkenyl groups such as an ethenyl group, a propenyl group and a butenyl group, and alkynyl groups such as an ethynyl group, a propynyl group and a butynyl group.

Examples of monovalent alicyclic hydrocarbon groups having 3 to 30 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

Examples of monovalent aromatic hydrocarbon groups having 6 to 30 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of heteroatoms that constitute the divalent heteroatom-containing linking group and the monovalent heteroatom-containing substituent include oxygen atoms, nitrogen atoms, sulfur atoms, phosphorus atoms, silicon atoms, and halogen atoms. Halogen atoms include, for example, fluorine, chlorine, bromine and iodine atoms.

Examples of the divalent heteroatom-containing liking groups include, for example, —O—, —C(═O)—, —S—, —C(═S)—, —NR′—, —SO₂—, or combinations of two or more of these and the like. R′ is a hydrogen atom or a monovalent hydrocarbon group.

Examples of the monovalent heteroatom-containing substituent include halogen atoms, a hydroxy group, a carboxy group, a cyano group, an amino group, a sulfanyl group, and the like.

The a is preferably 1 or 2, more preferably 1.

Examples of the monovalent organic group having 1 to 20 carbon atoms represented by R¹ include the same groups as groups having 1 to 20 carbon atoms among those exemplified as the monovalent organic group having 1 to 30 carbon atoms for X described above.

The halogen atom represented by R¹ includes, for example, a fluorine atom, a chlorine atom, a bromine atom, and an iodine atom.

R¹ is preferably a monovalent chain hydrocarbon group, a monovalent aromatic hydrocarbon group, or a monovalent group in which a part or all of the hydrogen atoms of the monovalent hydrocarbon group are replaced with a monovalent heteroatom-containing substituent, more preferably an alkyl group or an aryl group, and further preferably a methyl group, an ethyl group or a phenyl group.

The b is preferably 0 or 1, more preferably 0.

X in the formula (1) is preferably represented by the formula (1-1) (except for a case where X is represented by the formula (1-2) or the formula (1-3)), the formula (1-2) (except for a case where X is represented by the formula (1-3)), the formula (1-3), or the formula (1-4):

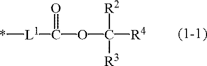

wherein L¹ is a single bond or a divalent linking group, * is a bond with a silicon atom in the formula (1), R² is a hydrogen atom or a monovalent hydrocarbon group having 1 to 10 carbon atoms, and R³ is a hydrogen atom or a monovalent hydrocarbon group having 1 to 10 carbon atoms and R⁴ is a monovalent hydrocarbon group having 1 to 10 carbon atoms or a monovalent heteroatom-containing group having 1 to 10 carbon atoms or R³ and R⁴ represent a 3- to 20-membered ring structure which R³ and R⁴ are combined together to form with a carbon atom to which these groups are bonded; [0039]

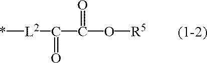

wherein L² is a single bond or a divalent linking group, * is a bond with a silicon atom in the formula (1), and R⁵ is a monovalent organic group having 1 to 10 carbon atoms;

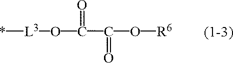

wherein L³ is a single bond or a divalent linking group, * is a bond with a silicon atom in the formula (1), and R⁶ is a monovalent organic group having 1 to 10 carbon atoms; and

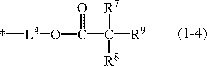

wherein L⁴ is a single bond or a divalent linking group, * is a bond with a silicon atom in the formula (1), and R⁷ is a hydrogen atom or a monovalent hydrocarbon group having 1 to 10 carbon atoms, and R⁸ is a hydrogen atom or a monovalent hydrocarbon group having 1 to 10 carbon atoms and R⁹ is a monovalent hydrocarbon group having 1 to 10 carbon atoms or a monovalent heteroatom-containing group having 1 to 10 carbon atoms or R⁸ and R⁹ represent a 3- to 20-membered ring structure which R⁸ and R⁹ are combined together to form with a carbon atom to which these groups are bonded.

Examples of the divalent linking group represented by L¹ in the formula (1-1), L² in the formula (1-2), L³ in the formula (1-3), or L⁴ in the formula (1-4) include a divalent organic group having 1 to 10 carbon atoms. Examples of the divalent organic group having 1 to 10 carbon atoms include groups obtained by removing one hydrogen atom from the monovalent organic groups having 1 to 10 carbon atoms among the monovalent organic groups having 1 to 30 carbon atoms exemplified above for X in the formula (1).

Among them, L¹, L², L³, and L⁴ are each preferably a divalent hydrocarbon group having 1 to 10 carbon atoms or a group in which a divalent heteroatom-containing group is present in a carbon-carbon bond of a divalent hydrocarbon group having 1 to 10 carbon atoms, more preferably an alkylene group, an alkenylene group, or a group in which —S— is present in a carbon-carbon bond of an alkylene group, even more preferably an alkylene group. A part or all of hydrogen atoms of these groups may be substituted with a monovalent heteroatom-containing substituent. As the monovalent heteroatom-containing substituent, the monovalent heteroatom-containing substituent exemplified above for X can suitably be employed.

As the monovalent hydrocarbon group having 1 to 10 carbon atoms represented by R², R³, or R⁴ in the formula (1-1) or R⁷, R⁸, or R⁹ in the formula (1-4), the monovalent hydrocarbon groups having 1 to 10 carbon atoms among the monovalent hydrocarbon groups having 1 to 30 carbon atoms exemplified above for X can suitably be employed.

Examples of the monovalent heteroatom-containing group having 1 to 10 carbon atoms represented by R⁴ in the formula (1-1) or R⁹ in the formula (1-4) include a group obtained by substituting a part or all of hydrogen atoms of the monovalent hydrocarbon group having 1 to 10 carbon atoms represented by R² or the like with a monovalent heteroatom-containing substituent. As the monovalent heteroatom-containing substituent, the monovalent heteroatom-containing substituents exemplified above for X can suitably be employed. Among them, a cyanoalkyl group having 1 to 5 carbon atoms such as a cyanomethyl group, a cyanoethyl group, or a cyanopropyl group and a fluorinated alkyl group having 1 to 5 carbon atoms such as a trifluoromethyl group or a 2,2,2-trifluoroethyl group are preferred.

Examples of the 3- to 20-membered ring structure which R³ and R⁴ are combined together to form with a carbon atom to which they are bonded in the formula (1-1) and the 3- to 20-membered ring structure which R⁸ and R⁹ are combined together to form with a carbon atom to which they are bonded in the formula (1-4) include an alicyclic structure, an aromatic ring structure, and a heterocyclic structure in which the divalent heteroatom-containing linking group exemplified above for X is present between carbon atoms in such a ring structure. A part or all of hydrogen atoms contained in the ring structure may be substituted with a substituent. As used herein, “-membered” refers to the number of atoms constituting the ring structure, and when the ring structure is polycyclic, “-membered” refers to the number of atoms constituting the polycyclic ring structure.

Examples of the alicyclic structure include structures having 3 to 20 carbon atoms among structures of the monovalent alicyclic hydrocarbon groups having 3 to 30 carbon atoms exemplified above for X. Examples of the aromatic ring structure include structures having 3 to 20 carbon atoms among structures of the monovalent aromatic hydrocarbon groups having 6 to 30 carbon atoms exemplified above for X. Examples of the heterocyclic structure include a lactone structure, a cyclic carbonate structure, a cyclic acetal, a cyclic ether, a sultone structure, and a structure containing a combination of two or more of them.

The heterocyclic structure is preferably a lactone structure. Examples of the lactone structure include monocyclic lactone structures such as a propiolactone structure, a butyrolactone structure, a valerolactone structure, a caprolactone structure, a cyclopentanelactone structure, a cyclohexanelactone structure, a polycyclic lactone structure such as a norbornanelactone structure, a benzobutyrolactone structure, and a benzovalerolactone structure. Among these, a butyrolactone structure and a norbornanelactone structure are preferable.

Examples of the substituent that substitutes a part or all of hydrogen atoms of the ring structure include: halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, a group obtained by substituting a hydrogen atom of such a group with a halogen atom; and an oxo group (═O).

When R³ and R⁴ or R⁸ and R⁹ form the ring structure, R² or R⁷ is preferably a hydrogen atom.

Examples of the monovalent organic group having 1 to 10 carbon atoms represented by R⁵ in the formula (1-2) or R⁶ in the formula (1-3) include the same groups as the groups having 1 to 10 carbon atoms among the monovalent organic groups having 1 to 30 carbon atoms exemplified above for X.

R⁴ in the formula (1-1), R⁵ in the formula (1-2), R⁶ in the formula (1-3), and R⁹ in the formula (1-4) are preferably each independently a monovalent heteroatom-containing group having 1 to 10 carbon atoms. When such a polar structure is contained, excellent pattern rectangularity can be achieved in alkali development. Examples of the monovalent heteroatom-containing group having 1 to 10 carbon atoms include the monovalent heteroatom-containing group having 1 to 10 carbon atoms represented by R⁴ or the like.

When X in the formula (1) is represented by the formula (1-1), examples of the first structural unit include structural units derived from compounds represented by the formulas (1-1-1) to (1-1-9 ) (hereinafter also referred to as “first structural unit (1-1-1) to first structural unit (1-1-9”).

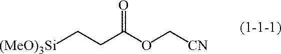

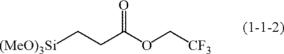

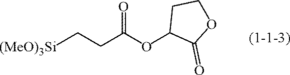

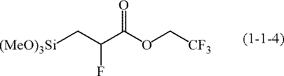

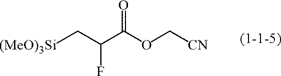

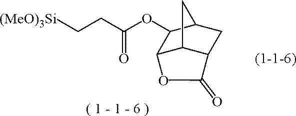

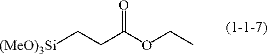

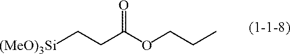

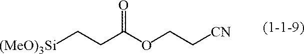

When X in the formula (1) is represented by the formula (1-2), examples of the first structural unit include structural units derived from compounds represented by the formulas (1-2-1) to (1-2-6) (hereinafter also referred to as “first structural unit (1-2-1) to first structural unit (1-2-6)”) .

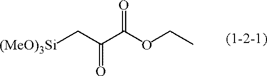

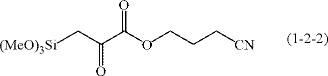

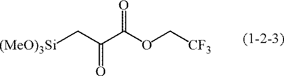

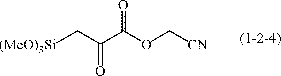

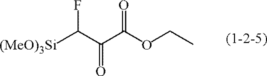

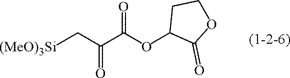

When X in the formula (1) is represented by the formula (1-3), examples of the first structural unit include structural units derived from compounds represented by the formulas (1-3-1) to (1-3-6) (hereinafter also referred to as “first structural unit (1-3-1) to first structural unit (1-3-6)”).

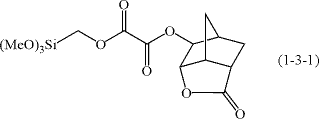

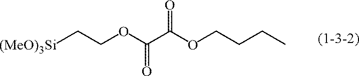

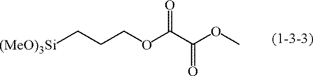

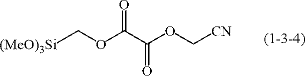

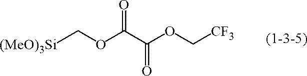

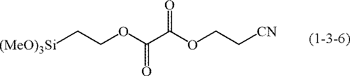

When X in the formula (1) is represented by the formula (1-4), examples of the first structural unit include structural units derived from compounds represented by the formulas (1-4-1) to (1-4-6) (hereinafter also referred to as “first structural unit (1-4-1) to first structural unit (1-4-6)”) .

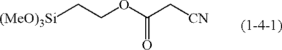

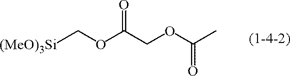

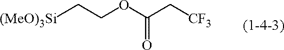

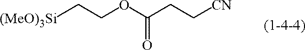

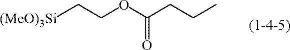

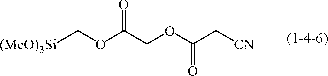

X in the formula (1) is preferably represented by the formula (1-3) or (1-4). In the case of these structures, high hydrophilicity is achieved by an alcoholic hydroxy group generated by dissociation of the alkali-dissociable group, and therefore generation of a residue can be prevented at a high level.

The lower limit of the content of the first structural unit in all structural units constituting the polysiloxane is preferably 5 mol%, more preferably 8 mol%, and even more preferably 10 mol%. Moreover, the upper limit of the content of the first structural unit is preferably 40 mol%, more preferably 35 mol%, and even more preferably 30 mol%. When the content of the first structural unit is within the above range, it is possible to efficiently form a silicon-containing film that makes it possible to form a resist pattern having excellent pattern rectangularity.

### (Second Structural Unit)

The polysiloxane preferably has a second structural unit represented by the formula (2) as a structural unit other than the first structural unit. When the polysiloxane has the second structural unit, the oxygen gas etching resistance of the silicon-containing film formed from the silicon-containing composition can be improved.

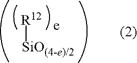

In the formula (2), R¹² is a substituted or unsubstituted monovalent alkoxy group having 1 to 20 carbon atoms, a hydroxy group, or a halogen atom, e is an integer of 0 to 3, and when e is 2 or more, a plurality of R¹²s are the same or different from each other.

Specific examples of the monovalent alkoxy group having 1 to 20 carbon atoms represented by R¹² in the formula (2) include alkoxy groups such as a methoxy group, an ethoxy group, an n-propoxy group, and an isopropoxy group. Further, the halogen atom includes a fluorine atom, a chlorine atom, a bromine atom, an iodine atom and the like.

In the formula (2), R¹² is preferably an alkoxy group, more preferably a methoxy group.

When the polysiloxane has the second structural unit, the lower limit of the content of the second structural unit in all structural units constituting the polysiloxane is preferably 40 mol%, more preferably 45 mol%, even more preferably 50 mol%. The upper limit of the content of the second structural unit is preferably 95 mol%, more preferably 90 mol%, and even more preferably 85 mol%.

### (Third Structural Unit)

The polysiloxane may have a third structural unit represented by the formula (3) as a structural unit other than the first structural unit. By having the third structural unit, it is possible to exhibit an antireflection effect on the resist film during exposure and form a resist pattern having excellent cross-sectional rectangularity.

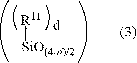

In the formula (3), R¹¹ is a substituted or unsubstituted aryl group having 6 to 20 carbon atoms. d is an integer of 1 to 3. When d is 2 or more, a plurality of R¹¹s are the same or different from each other.

Examples of the aryl group having 6 to 20 carbon atoms represented by R¹¹ include a phenyl group, a naphthyl group, an anthracenyl group, and the like.

Examples of substituents for the aryl group include alkyl groups having 1 to 5 carbon atoms, a hydroxy group, and a halogen atom. Among them, a halogen atom is preferred, and a fluorine atom is more preferred.

The third structural unit includes, for example, a structural unit derived from a compound represented by the formulas (3-1) to (3-8) (hereinafter also referred to as “third structural unit (1) to third structural unit (8)”) and the like.

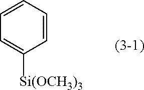

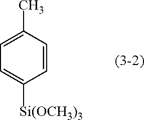

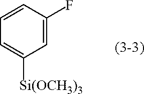

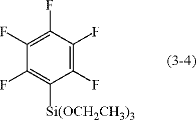

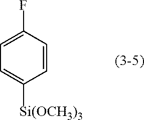

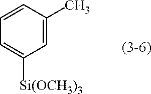

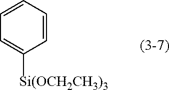

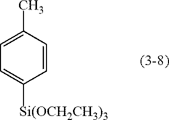

When the polysiloxane has the third structural unit, the lower limit of the content of the third structural unit in all structural units constituting the polysiloxane is preferably 1 mol%, more preferably 5 mol%, and further preferably 8 mol%. The upper limit of the content of the third structural unit is preferably 30 mol%, more preferably 20 mol%, and even more preferably 15 mol%. When the content of the third structural unit is within the above range, a silicon-containing film having more excellent antireflection performance can be formed.

### (Fourth Structural Unit)

The polysiloxane preferably has a fourth structural unit represented by the formula (4) as another structural unit other than the first structural unit.

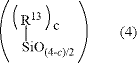

In the formula (4), R¹³ is a substituted or unsubstituted alkyl group having 1 to 10 carbon atoms. c is an integer of 1 to 3. When c is 2 or more, a plurality of R¹³_{S} are the same or different from each other.

Examples of the alkyl group having 1 to 10 carbon atoms represented by R¹³ include a methyl group, an ethyl group, a n-propyl group, an i-propyl group, a n-butyl group, an i-butyl group, a t-butyl group and the like.

The substituents of the alkyl group include halogen atoms such as a fluorine atom, a chlorine atom, a bromine atom, and an iodine atom. The alkyl group having 1 to 10 carbon atoms represented by R¹³ is preferably unsubstituted.

The c is preferably 1 or 2, more preferably 1.

When the polysiloxane has the fourth structural unit, the lower limit of the content of the fourth structural unit in all structural units constituting the second polysiloxane is preferably 4 mol%, more preferably 6 mol%, and even more preferably 8 mol%. The upper limit of the content is preferably 30 mol%, more preferably 20 mol%, even more preferably 15 mol%, and particularly preferably 85 mol%. By setting the content of the fourth structural unit in the polysiloxane within the above range, the silicon-containing film formed by the silicon-containing composition can impart excellent cross-sectional rectangularity to the resist pattern.

The lower limit of the content of the polysiloxane (the total content when multiple types of polysiloxanes are included) in the silicon-containing composition is preferably 0.1% by mass, more preferably 0.5% by mass, and even more preferably 1% by mass based on all components contained in the silicon-containing composition. The upper limit of the content is preferably 10% by mass, more preferably 7.5% by mass, and even more preferably 5% by mass.

The polysiloxane is preferably in the form of a polymer. As used herein, the term “polymer” refers to a compound having two or more structural units, and when two or more identical structural units are consecutive in a polymer, the structural units are also referred to as “repeating units”. When the polysiloxane is in the form of a polymer, the lower limit of the polystyrene-equivalent weight average molecular weight (Mw) of the polysiloxane by gel permeation chromatography (GPC) is preferably 1,000, more preferably 1,100, even more preferably 1,200, and particularly preferably 1,500. The upper limit of Mw is preferably 8,000, more preferably 5,000, still more preferably 3,000, and particularly preferably 2,800. The method for measuring the Mw of polysiloxane is as described in Examples.

### [Method for Synthesizing Polysiloxane]

The polysiloxane can be synthesized by a conventional method using monomers that provide each structural unit. For example, a monomer that provides the first structural unit and optionally a monomer that provides other structural units can be hydrolyzed and condensed in a solvent in the presence of a catalyst such as oxalic acid and water, and preferably a solution containing the produced hydrolytic condensate can be purified by performing solvent substitution or the like in the presence of a dehydrating agent such as trimethyl orthoformate to synthesize the polysiloxane. It is believed that each monomer is incorporated into the polysiloxane by hydrolytic condensation reaction or the like regardless of its type. Therefore, each content of the first structural unit and the other structural units in the synthesized polysiloxane is usually equal to the ratio of the charged amount of each monomer used in the synthesis reaction.

### [Solvent]

The solvent is not particularly limited, and examples thereof include alcohol-based solvents, ketone-based solvents, ether-based solvents, ester-based solvents, nitrogen-containing solvents, and water. The silicon-containing composition may contain one or more solvents.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, methyl ethyl ketone, methyl-n-propyl ketone, methyl-iso-butyl ketone, cyclohexanone and the like.

Examples of ether solvents include ethyl ether, isopropyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N,N-dimethylformamide, N,N-dimethylacetamide, N-methylpyrrolidone, and the like.

Among these, ether-based solvents or ester-based solvents are preferable, and ether-based solvents or ester-based solvents having a glycol structure are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable, and propylene glycol monoethyl ether is more preferable.

The lower limit of the content of the solvent in the silicon-containing composition is preferably 90% by mass, more preferably 92.5% by mass, and even more preferably 95% by mass, relative to all components contained in the silicon-containing composition. The upper limit of the content is preferably 99.9% by mass, more preferably 99.5% by mass, and even more preferably 99% by mass.

### (Optional Component)

Examples of optional components include photo-acid generators, basic compounds (including base generators), acid diffusion controlling agent, radical generators, surfactants, colloidal silica, colloidal alumina, and organic polymers. The silicon-containing composition can contain one or more optional components.

When the silicon-containing composition contains optional components, the content of the optional component in the silicon-containing composition can be appropriately determined according to the type of the optional components used and within a range that does not impair the effects of the present invention.

### Method for Preparing Silicon-Containing Composition

The method for preparing the silicon-containing composition is not particularly limited, and it can be prepared according to a conventional method. For example, a solution of the polysiloxane, a solvent, and optionally optional components are mixed in a predetermined ratio, and the resulting mixed solution is preferably filtered through a filter having a pore size of 0.2 µm or less to prepare the silicon-containing composition.

### Method for Manufacturing Semiconductor Substrate

A method for manufacturing a semiconductor substrate according to the present embodiment includes: directly or indirectly applying a silicon-containing composition to a substrate to form a silicon-containing film (hereinafter, also referred to as a “silicon-containing film forming step”); directly or indirectly applying a composition for forming a resist film to the silicon-containing film to form the resist film (hereinafter, also referred to as a “resist film forming step”); exposing the resist film to radiation (hereinafter, also referred to as an “exposing step”); developing the exposed resist film to form a resist pattern (hereinafter, also referred to as a “developing step”). In the silicon-containing film forming step in the method for manufacturing a semiconductor substrate, the above-described silicon-containing composition is used as the silicon-containing composition.

The method for manufacturing a semiconductor substrate may further include, if necessary, directly or indirectly forming an organic underlayer film on the substrate (hereinafter, also referred to as an “organic underlayer film forming step”) before the silicon-containing film forming step.

Further, the method for manufacturing a semiconductor substrate may further include, after the developing step, etching the silicon-containing film using the resist pattern as a mask to form a silicon-containing film pattern (hereinafter, also referred to as a “silicon-containing film pattern forming step”), performing etching using the silicon-containing film pattern as a mask (hereinafter, also referred to as an “etching step”), and removing the silicon-containing film pattern by a basic liquid (hereinafter, also referred to as a “removing step”).

According to the method for manufacturing a semiconductor substrate, by using the above-described silicon-containing composition as the silicon-containing composition in the silicon-containing film forming step, the resist pattern having excellent cross-sectional shape rectangularity can be formed on the silicon-containing film.

Hereinbelow, each of the steps of the method for manufacturing a semiconductor substrate will be described with reference to a case where the method includes the organic underlayer film forming step before the silicon-containing film forming step and the silicon-containing film pattern forming step, the etching step, and the removing step after the developing step.

### [Organic Underlayer Film Forming Step]

In this step, an organic underlayer film is formed directly or indirectly on the substrate before the silicon-containing film forming step. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### [Silicon-Containing Film Forming Step]

In this step, the silicon-containing composition is directly or indirectly applied to the substrate to form a silicon-containing film. By this step, a coating film of the silicon-containing composition is formed directly or indirectly on the substrate, and the coating film is usually cured by heating to form a silicon-containing film.

In this step, the silicon-containing composition described above is used as the silicon-containing composition.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method of applying the silicon-containing composition is not particularly limited, and examples thereof include a spin coating method.

Examples of the case of indirectly applying the silicon-containing composition to the substrate include, for example, the case of applying the silicon-containing composition onto another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the composition for forming a silicon-containing film contains an acid generator, and the acid generator is a radiation-sensitive acid generator, the formation of the silicon-containing film can be accelerated by combining heating and exposure. Radiation used for exposure includes, for example, the same radiation as exemplified in the exposing step described later.

The lower limit of the average thickness of the silicon-containing film formed by this step is preferably 1 nm, more preferably 3 nm, and even more preferably 5 nm. The upper limit of the average thickness is preferably 500 nm, more preferably 300 nm, and even more preferably 200 nm. The method for measuring the average thickness of the silicon-containing film is described in Examples.

### [Resist Film Forming Step]

In this step, a composition for forming a resist film is directly or indirectly applied to the silicon-containing film to form the resist film. Through this step, a resist film is formed directly or indirectly on the silicon-containing film.

The method of applying the composition for forming a resist film is not particularly limited, and examples thereof include a spin coating method.

To explain this step in more detail, for example, after applying a resist composition so that the formed resist film has a predetermined thickness, pre-baking (hereinafter also referred to as “PB”) is performed to volatilize the solvent to form a resist film.

The PB temperature and PB time can be appropriately determined according to the type of resist film forming composition used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

As the composition for forming a resist film used in this step, a so-called positive-type composition for forming a resist film for alkali development is preferably used. In the silicon-containing film formed above, the alkali-dissociable group of the polysiloxane is dissociated by an alkaline solution for alkali development so that the solubility of the resist film near the interface between the resist film and the silicon-containing film increases, which makes it possible to form a resist pattern having excellent pattern rectangularity. Such a composition for forming a resist film is preferably a positive-type composition for forming a resist film containing, for example, a resin having an acid-dissociable group and a radiation-sensitive acid generator and intended for exposure to ArF excimer laser light (for ArF exposure) or exposure to extreme ultraviolet (for EUV exposure).

### [Exposing Step]

In this step, the resist film formed by the resist film forming step is exposed to radiation. This step causes a difference in solubility in an alkaline solution, which is a developer, between an exposed portion and an unexposed portion of the resist film. More specifically, the solubility of the exposed portion of the resist film to an alkaline solution increases.

The radiation used for exposure can be appropriately selected according to the type of a composition for forming a resist film used. Examples thereof include electromagnetic waves such as visible light, ultraviolet rays, far ultraviolet rays, X-rays and γ-rays, and particle beams such as electron beams, molecular beams and ion beams. Among these, far ultraviolet rays are preferable, and KrF excimer laser light (wavelength 248 nm), ArF excimer laser light (wavelength 193 nm), F₂ excimer laser light (wavelength 157 nm), Kr₂ excimer laser light (wavelength 147 nm), ArKr excimer laser light (wavelength of 134 nm) or extreme ultraviolet rays (wavelength of 13.5 nm, etc., also referred to as “EUV”) are more preferred, and ArF excimer laser light or EUV is even more preferred. Also, the exposure conditions can be appropriately determined according to the type of the composition for forming a resist film to be used.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, the exposed resist film is developed. The development of the exposed resist film is preferably alkali development. Due to the above exposing step, the solubility in the alkaline solution, which is the developer, differs between the exposed area and the unexposed area in the resist film. A resist pattern is formed by removing the exposed portion, which is relatively soluble in an alkaline solution, by carrying out alkali development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of a developer used for organic solvent development include the same developer as those exemplified as the solvent for the silicon-containing composition described above.

In this step, washing and/or drying may be performed after the development.

### [Silicon-Containing Film Pattern Forming Step]

In this step, the silicon-containing film is etched using the resist pattern as a mask to form a silicon-containing film pattern.

The above etching may be dry etching or wet etching, but dry etching is preferred.

Dry etching can be performed using, for example, a known dry etching apparatus. The etching gas used for dry etching can be appropriately selected according to the elemental composition of the silicon-containing film to be etched, and for example, fluorine-based gases such as CHF₃, CF₄, C₂F₆, C₃F₈ and SF₆, chlorine-based gases such as Cl₂ and BCl₃, oxygen-based gases such as O₂, O₃ and H₂O, reducing gases such as H₂, CO, CO₂, CH₄, C₂H₂, C₂H₄, C₂H₆, C₃H₄, C₃H₆, C₃H₈, HF, HI, HBr, HC1, NO and NH₃, and inert gases such as He, N₂ and Ar are used. These gases can also be mixed and used. For dry etching of a silicon-containing film, a fluorine-based gas is usually used, and a mixture of a fluorine-based gas, an oxygen-based gas and an inert gas is preferably used.

### [Etching Step]

In this step, etching is performed using the silicon-containing film pattern as a mask. More specifically, etching is performed one or more times using as a mask the pattern formed in the silicon-containing film obtained in the silicon-containing film pattern forming step to obtain a patterned substrate.

When an organic underlayer film is formed on the substrate, the organic underlayer film is etched using the silicon-containing film pattern as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the silicon-containing film and the organic underlayer film to be etched. As the etching gas, the gas for etching the silicon-containing film described above can be suitably used, and these gases can also be mixed and used. An oxygen-based gas is usually used for dry etching of the organic underlayer film using the silicon-containing film pattern as a mask.

Dry etching for forming a pattern on the substrate using the organic underlayer film pattern as a mask can be performed using a known dry etching apparatus. The etching gas used for dry etching can be appropriately selected depending on the elemental composition of the organic underlayer film and the substrate to be etched, and the like. For example, etching gases similar to those exemplified as the etching gas used for the dry etching of the organic underlayer film may be used. Etching may be performed a plurality of times with different etching gases. After the etching step, if the silicon-containing film remains on the substrate, or on the resist underlayer pattern, etc., the silicon-containing film can be removed by performing the removing step described below.

### [Removing Step]

In this step, the silicon-containing film pattern is removed with a basic liquid. This step removes the silicon-containing film from the substrate. Also, the silicon-containing film residue after etching can be removed.

The basic liquid is not particularly limited as long as it is a basic solution containing a basic compound. Examples of basic compounds include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (hereinafter also referred to as “TMAH”), tetraethylammonium hydroxide, pyrrole, piperidine, choline, 1,8-diazabicyclo[5.4.0]-7-undecene, 1,5-diazabicyclo[4.3.0]-5-nonene and the like. Among these, ammonia is preferable from the viewpoint of avoiding damage to the substrate.

From the viewpoint of further improving the removability of the silicon-containing film, the basic liquid is preferably a liquid containing a basic compound and water, or a liquid containing a basic compound, hydrogen peroxide and water.

The method for removing the silicon-containing film is not particularly limited as long as it is a method that allows the silicon-containing film and the basic liquid to come into contact with each other. Examples thereof include a method of immersing a substrate in a basic liquid, a method of spraying a basic liquid, a method of applying a basic liquid, and the like.

The temperature, time, and other conditions for removing the silicon-containing film are not particularly limited, and can be appropriately determined according to the film thickness of the silicon-containing film, the type of basic liquid used, and the like. The lower limit of the temperature is preferably 20° C., more preferably 40° C., and even more preferably 50° C. The upper limit of the temperature is preferably 300° C., more preferably 100° C. The lower limit of the time is preferably 5 seconds, more preferably 30 seconds. The upper limit of the time is preferably 10 minutes, more preferably 180 seconds.

In this step, washing and/or drying may be performed after removing the silicon-containing film.

### EXAMPLES

Hereinbelow, the present disclosure will specifically be described on the basis of examples, but is not limited to these examples.

### (Measurement of Weight Average Molecular Weight (Mw)]

The weight average molecular weight (Mw) of the polysiloxane was measured by gel permeation chromatography (GPC) using GPC columns, available from Tosoh Corporation (“G2000HXL” × 2, “G3000HXL” × 1, and “G4000HXL” × 1) under the following conditions.

### (Measurement Conditions)

Eluant: tetrahydrofuran
Flow rate: 1.0 mL/min
Sample concentration: 1.0% by mass
Sample injection amount: 100 µL
Column temperature: 40° C.
Detector: differential refractometer
Standard substance: monodisperse polystyrene

### Concentration of Polysiloxane in Solution

The concentration (unit: % by mass) of the solution of the polysiloxane was calculated by firing 0.5 g of the solution of the polysiloxane at 250° C. for 30 minutes, measuring a mass of a residue thus obtained, and dividing the mass of the residue by the mass of the solution of the polysiloxane.

### Average Thickness of Silicon-Containing Film

The average thickness of the silicon-containing film formed on a 12-inch silicon wafer was measured by using a spectroscopic ellipsometer (“M2000D”, available from J. A. WOOLLAM Company). More specifically, thicknesses of the silicon-containing film formed on the 12 inch-silicon wafer were measured at optional nine points located at an interval of 5 cm including the center of the silicon-containing film, and the average value of the film thicknesses was calculated, and taken as the average thickness.

### <Synthesis of Polysiloxane>

Monomers (hereinafter, also referred to as “monomers (M-1) to (M-17)”) used for synthesis in Synthesis Example 1 to Synthesis Example 20 are shown below. In the following Synthesis Example 1 to Synthesis Example 20, mol% means a value for each monomer when the total number of moles of the monomers (M-1) to (M-17) used is 100 mol%.

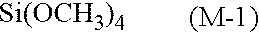

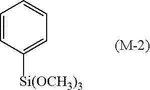

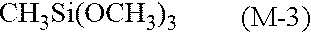

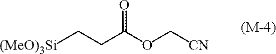

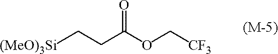

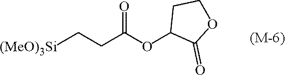

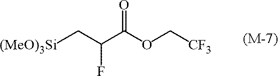

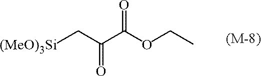

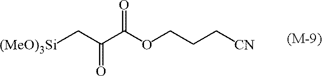

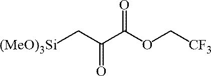

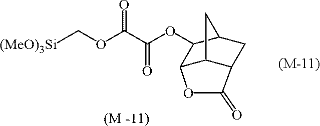

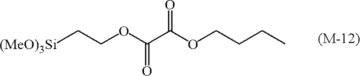

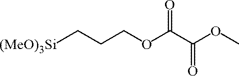

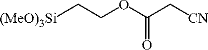

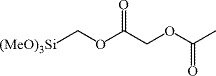

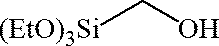

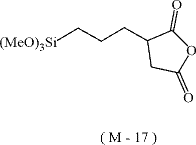

### [Synthesis Example 1] Synthesis of Polysiloxane (A-1)

In a reaction vessel, the compound (M-1), the compound (M-3), and the compound (M-4) were dissolved in 62 parts by mass of propylene glycol monoethyl ether so that the molar ratio of the compounds was 80/10/10 (mol%) to prepare a monomer solution. A temperature in the reaction vessel was set to 60° C., and 40 parts by mass of a 9.1% by mass oxalic acid aqueous solution was added dropwise thereto over 20 minutes with stirring. The reaction was performed for 4 hours with the start of the dropwise addition as the start time of the reaction. After the completion of the reaction, the inside of the reaction vessel was cooled to 30° C. or lower. After 550 parts by mass of propylene glycol monoethyl ether was added to the cooled reaction solution, water, alcohols produced by the reaction, and excessive propylene glycol monoethyl ether were removed using an evaporator to obtain a propylene glycol monoethyl ether solution of a polysiloxane (A-1). The Mw of the polysiloxane (A-1) was 1,600. The concentration of the polysiloxane (A-1) in the propylene glycol monoethyl ether solution was 7.2% by mass.

### [Synthesis Example 2 to Synthesis Example 20] Synthesis of Polysiloxanes (A-2) to (A-17) and (a-1) to (a-3)

Propylene glycol monoethyl ether solutions of the polysiloxanes (A-2) to (A-17) and (a-1) to (a-3) were obtained in the same manner as in Synthesis Example 1 except that the types and amounts of monomers shown in the following Table 1 were used. In the following Table 1, “-” in the monomers indicates that the corresponding monomer was not used. The Mw of the obtained polysiloxane and the concentration (% by mass) of the polysiloxane in the solution are also shown in the following Table 1.

TABLE 1

| | Polysiloxane | Charge amount of each monomer (mol%) | | | | | | | | | | | | | | | | | Mw | Concentration of polysiloxane in solution (% by mass) |
|---|---|---|---|---|---|---|---|---|---|---|---|---|---|---|---|---|---|---|---|---|
| | | Monomer to give second structural unit | Monomer to give fourth structural unit | Monomer to give third structural unit | Monomer to give first structural unit | | | | | | | | | | | | Monomer to give another structural unit | | | |
| | | M-1 | M-3 | M-2 | M-4 | M-5 | M-6 | M-7 | M-8 | M-9 | M-10 | M-11 | M-12 | M-13 | M-14 | M-15 | M-16 | M-17 | | |
| Synthesis Example 1 | A-1 | 80 | 10 | - | 10 | - | - | - | - | - | - | - | - | - | - | - | - | - | 1600 | 7.2 |
| Synthesis Example 2 | A-2 | 80 | 10 | - | - | 10 | - | - | - | - | - | - | - | - | - | - | - | - | 1700 | 6.9 |
| Synthesis Example 3 | A-3 | 83 | 12 | - | - | - | 5 | - | - | - | - | - | - | - | - | - | - | - | 1500 | 7.5 |
| Synthesis Example 4 | A-4 | 80 | 10 | - | - | - | 10 | - | - | - | - | - | - | - | - | - | - | - | 1600 | 7.5 |
| Synthesis Example 5 | A-5 | 70 | 10 | - | - | - | 20 | - | - | - | - | - | - | - | - | - | - | - | 1900 | 7.5 |
| Synthesis Example 6 | A-6 | 60 | 10 | - | - | - | 30 | - | - | - | - | - | - | - | - | - | - | - | 2500 | 7.3 |
| Synthesis Example 7 | A-7 | 80 | 10 | - | - | - | - | 10 | - | - | - | - | - | - | - | - | - | - | 1500 | 7.0 |
| Synthesis Example 8 | A-8 | 80 | 10 | - | - | - | - | - | 10 | - | - | - | - | - | - | - | - | - | 2600 | 6.6 |
| Synthesis Example 9 | A-9 | 80 | 10 | - | - | - | - | - | - | 10 | - | - | - | - | - | - | - | - | 2000 | 7.5 |
| Synthesis Example 10 | A-10 | 80 | 10 | - | - | - | - | - | - | - | 10 | - | - | - | - | - | - | - | 2000 | 6.9 |
| Synthesis Example 11 | A-11 | 80 | 10 | - | - | - | - | - | - | - | - | 10 | - | - | - | - | - | - | 1600 | 7.5 |
| Synthesis Example 12 | A-12 | 80 | 10 | - | - | - | - | - | - | - | - | - | 10 | - | - | - | - | - | 2200 | 7.0 |
| Synthesis Example 13 | A-13 | 85 | 10 | - | - | - | - | - | - | - | - | - | - | 5 | - | - | - | - | 2,700 | 7.3 |
| Synthesis Example 14 | A-14 | 80 | 10 | - | - | - | - | - | - | - | - | - | - | 10 | - | - | - | - | 2,700 | 7.3 |
| Synthesis Example 15 | A-15 | 60 | 10 | - | - | - | - | - | - | - | - | - | - | 30 | - | - | - | - | 2,700 | 7.0 |
| Synthesis Example 16 | A-16 | 80 | 10 | - | - | - | - | - | - | - | - | - | - | - | 10 | - | - | - | 2,500 | 7.2 |
| Synthesis Example 17 | A-17 | 80 | 10 | - | - | - | - | - | - | - | - | - | - | - | - | 10 | - | - | 2,300 | 7.8 |
| Synthesis Example 18 | a-1 | 80 | 10 | 10 | - | - | - | - | - | - | - | - | - | - | - | - | - | - | 1800 | 7.4 |
| Synthesis Example 19 | a-2 | 80 | 10 | - | - | - | - | - | - | - | - | - | - | - | - | - | 10 | - | 1600 | 7.3 |
| Synthesis Example 20 | a-3 | 80 | 10 | - | - | - | - | - | - | - | - | - | - | - | - | - | - | 10 | 1500 | 7.1 |

### <Preparation of Silicon-Containing Composition>

A solvent and a photo-acid generator used for preparing the silicon-containing composition are shown below. In the following Examples 1 to 19 and Comparative Examples 1 to 3, unless otherwise specified, parts by mass represents a value when the total mass of components used is 10,000 parts by mass.

### Solvent

B-1: Propylene glycol monoethyl ether [C] Photo-acid generator
C-1: A compound represented by the formula (C-1).

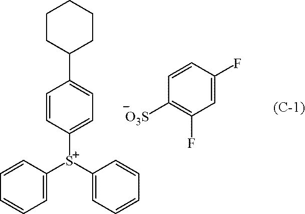

### [Example 1] Preparation of Silicon-Containing Composition (J-1)

100 parts by mass of a polysiloxane (A-1) and 9900 parts by mass of a solvent (B-1) (a solvent contained in the solution of the polysiloxane was also included) were mixed, and the obtained solution was filtered through a polytetrafluoroethylene filter having a pore size of 0.2 µm to prepare a silicon-containing composition (J-1).

### Examples 2 to 19 and Comparative Examples 1 to 3

### Preparation of Silicon-Containing Compositions (J-2) to (J-19) and (j-1) to (j-3)

Silicon-containing compositions (J-2) to (J-19) of Examples 2 to 19 and silicon-containing compositions (j-1) to (j-3) of Comparative Examples 1 to 3 were prepared in the same manner as in Example 1 except that respective components of types and blending amounts shown in the following Table 2 were used.

### <Evaluation>

Using the compositions prepared as described above, pattern rectangularity was evaluated by the following method. The evaluation results are shown in the following Table 2.

### [Pattern Rectangularity (ArF Immersion Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each silicon-containing composition for ArF exposure prepared as described above was applied on the organic underlayer film, and subjected to heating at 220° C. for 60 sec, followed by cooling at 23° C. for 30 sec to form a silicon-containing film having an average thickness of 20 nm. A radiation-sensitive resin composition (“ARF AR2772JN”, available from JSR Corporation) was applied on each silicon-containing film formed as described above, and heating was conducted at 90° C. for 60 sec, followed by cooling at 23° C. for 30 sec to form a resist film having an average thickness of 100 nm. Then, using an ArF immersion exposure apparatus (“S610C”, available from NIKON), the substrate was exposed through a mask having a mask size for 40 nm line/80 nm pitch formation under optical conditions of NA: 1.30 and Dipole, then heated at 100° C. for 60 sec, followed by cooling at 23° C. for 60 sec. Thereafter, development was performed by a paddle method using a 2.38% by mass aqueous TMAH solution (20° C. to 25° C.), followed by washing with water and drying, thereby obtaining a substrate for evaluation having a resist pattern formed thereon. A scanning electron microscope (“CG-4000”, available from Hitachi High-Technologies Corporation) was used for measuring the length of the resist pattern of the substrate for evaluation and observing the cross-sectional shape of the resist pattern. The pattern rectangularity of a 1 : 1 line and space pattern with a line width of 40 nm in the substrate for evaluation was evaluated as “A” (good) when the cross-sectional shape of the pattern was rectangular, “B” (slightly good) when trailing was present in the cross-sectional shape of the pattern (trailing was observed in the spaces of the resist pattern), and “C” (poor) when a residue (defect) was present in the pattern.

### <Preparation of Resist Composition for EUV Exposure>

A resist composition for EUV exposure (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content of each structural unit contained: (1)/(2)/(3) = 65/5/30 (mol%)), 1.0 parts by mass of triphenylsulfonium trifluoromethanesulfonate as a radiation-sensitive acid generating agent, and 4,400 parts by mass of ethyl lactate and 1,900 parts by mass of propylene glycol monomethyl ether acetate each as a solvent, and filtering the obtained solution through a filter having a pore size of 0.2 µm.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. Each silicon-containing composition was applied on the organic underlayer film, and subjected to heating at 220° C. for 60 sec, followed by cooling at 23° C. for 30 sec to form a silicon-containing film having an average thickness of 20 nm. A resist composition for EUV exposure (R-1) was applied on each silicon-containing film formed as described above, and heating was conducted at 130° C. for 60 sec, followed by cooling at 23° C. for 30 sec to form a resist film having an average thickness of 50 nm. Next, the resist film was irradiated with extreme ultraviolet rays using an EUV scanner (“TWINSCAN NXE:3300B”, available from ASML Co. (NA = 0.3; Sigma = 0.9; quadrupole illumination, with a 1 : 1 line and space mask having a line width of 25 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous TMAH solution (20° C. to 25° C.), followed by washing with water and drying, thereby obtaining a substrate for evaluation having a resist pattern formed thereon. The scanning electron microscope was used for measuring the length of the resist pattern of the substrate for evaluation and observing the resist pattern. The rectangularity of a 1 : 1 line and space pattern with a line width of 25 nm in the substrate for evaluation was evaluated as “A” (good) when the cross-sectional shape of the pattern was rectangular, “B” (slightly good) when trailing was present in the cross-sectional shape of the pattern (trailing was observed in the spaces of the resist pattern), and “C” (poor) when a residue (defect) was present in the pattern.

TABLE 2

| | Silicon-containing composition | Polysiloxane | | Solvent | | Photo-acid generator | | Pattern rectangularity | |
|---|---|---|---|---|---|---|---|---|---|
| | | Type | Blending amount (parts by mass) | Type | Blending amount (parts by mass) | Type | Blending amount (parts by mass) | ArF immersion exposure | EUV exposure |
| Example 1 | J-1 | A-1 | 100 | B-1 | 9900 | - | - | A | A |
| Example 2 | J-2 | A-2 | 100 | B-1 | 9900 | - | - | A | A |
| Example 3 | J-3 | A-3 | 100 | B-1 | 9900 | - | - | A | A |
| Example 4 | J-4 | A-4 | 100 | B-1 | 9900 | - | - | A | A |
| Example 5 | J-5 | A-5 | 100 | B-1 | 9900 | - | - | A | A |
| Example 6 | J-6 | A-6 | 100 | B-1 | 9900 | - | - | B | B |
| Example 7 | J-7 | A-7 | 100 | B-1 | 9900 | - | - | A | A |
| Example 8 | J-8 | A-8 | 100 | B-1 | 9900 | - | - | A | A |
| Example 9 | J-9 | A-9 | 100 | B-1 | 9900 | - | - | A | A |
| Example 10 | J-10 | A-10 | 100 | B-1 | 9900 | - | - | A | A |
| Example 11 | J-11 | A-11 | 100 | B-1 | 9900 | - | - | A | A |
| Example 12 | J-12 | A-12 | 100 | B-1 | 9900 | - | - | A | A |
| Example 13 | J-13 | A-13 | 100 | B-1 | 9900 | - | - | A | A |
| Example 14 | J-14 | A-14 | 100 | B-1 | 9900 | - | - | A | A |
| Example 15 | J-15 | A-15 | 100 | B-1 | 9900 | - | - | A | A |
| Example 16 | J-16 | A-16 | 100 | B-1 | 9900 | - | - | A | A |
| Example 17 | J-17 | A-17 | 100 | B-1 | 9900 | - | - | A | A |
| Example 18 | J-18 | A-4 | 100 | B-1 | 9900 | C-1 | 3 | A | A |
| Example 19 | J-19 | A-14 | 100 | B-1 | 9900 | C-1 | 3 | A | A |
| Comparative Example 1 | j-1 | a-1 | 100 | B-1 | 9900 | - | - | C | C |
| Comparative Example 2 | j-2 | a-2 | 100 | B-1 | 9900 | C-1 | 3 | C | C |
| Comparative Example 3 | j-3 | a-3 | 100 | B-1 | 9900 | - | - | C | C |

As is apparent from the results in the above Table 2, the silicon-containing films formed from the silicon-containing compositions of Examples could form a resist pattern having more excellent cross-sectional shape rectangularity on the film than that of the silicon-containing films formed from the silicon-containing compositions of Comparative Examples.

A silicon-containing composition and a method for manufacturing a semiconductor substrate of the present disclosure can form a silicon-containing film capable of forming a resist pattern having excellent cross-sectional shape rectangularity. Therefore, these can be suitably used for manufacturing the semiconductor substrate and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A silicon-containing composition comprising:
a polysiloxane comprising a first structural unit represented by formula (1); and
a solvent: 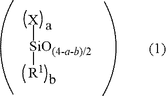
wherein X is an alkali-dissociable group, a is an integer of 1 to 3, when a is 2 or more, a plurality of Xs are the same or different from each other, R¹ is a monovalent organic group having 1 to 20 carbon atoms, a hydroxy group, or a halogen atom, b is an integer of 0 to 2, when b is 2, two R¹s are the same or different from each other, and a + b is 3 or less.

2. The silicon-containing composition according to claim 1, wherein X in the formula (1) is represented by formula (1-1), formula (1-2), formula (1-3), or formula (1-4), provided that when X is represented by the formula (1-1), X is not represented by the formula (1-2) or the formula (1-3), and that when X is represented by the formula (1-2), X is not represented by the formula (1-3): 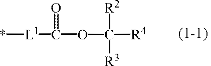
wherein:
L¹ is a single bond or a divalent linking group;
* is a bond with a silicon atom in the formula (1);
R² is a hydrogen atom or a monovalent hydrocarbon group having 1 to 10 carbon atoms; and
R³ is a hydrogen atom or a monovalent hydrocarbon group having 1 to 10 carbon atoms and R⁴ is a monovalent hydrocarbon group having 1 to 10 carbon atoms or a monovalent heteroatom-containing group having 1 to 10 carbon atoms, or R³ and R⁴ taken together represent a 3- to 20-membered ring structure together with the carbon atom to which R³ and R⁴ are bonded, 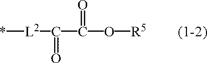
wherein:
L² is a single bond or a divalent linking group;
* is a bond with a silicon atom in the formula (1); and
R⁵ is a monovalent organic group having 1 to 10 carbon atoms, 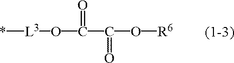
wherein:
L³ is a single bond or a divalent linking group;
* is a bond with a silicon atom in the formula (1); and
R⁶ is a monovalent organic group having 1 to 10 carbon atoms, and 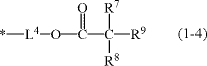
wherein:
L⁴ is a single bond or a divalent linking group;
* is a bond with a silicon atom in the formula (1);
R⁷ is a hydrogen atom or a monovalent hydrocarbon group having 1 to 10 carbon atoms; and
R⁸ is a hydrogen atom or a monovalent hydrocarbon group having 1 to 10 carbon atoms and R⁹ is a monovalent hydrocarbon group having 1 to 10 carbon atoms or a monovalent heteroatom-containing group having 1 to 10 carbon atoms, or R⁸ and R⁹ taken together represent a 3- to 20-membered ring structure together with the carbon atom to which R⁸ and R⁹ are bonded.

3. The silicon-containing composition according to claim 2, wherein R⁴ in the formula (1-1), R⁵ in the formula (1-2), R⁶ in the formula (1-3), and R⁹ in the formula (1-4) are each independently a monovalent heteroatom-containing group having 1 to 10 carbon atoms.

4. The silicon-containing composition according to claim 1, wherein a content of the first structural unit in the polysiloxane relative to all structural units constituting the polysiloxane is 0.5 mol% or more and 40 mol% or less.

5. The silicon-containing composition according to claim 1, wherein the polysiloxane further comprises a second structural unit represented by formula (2): 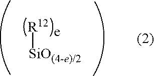
wherein R¹² is a substituted or unsubstituted monovalent alkoxy group having 1 to 20 carbon atoms, a hydroxy group, or a halogen atom, e is an integer of 0 to 3, and when e is 2 or more, a plurality of R¹²s are the same or different from each other.

6. The silicon-containing composition according to claim 5, wherein a content of the second structural unit in the polysiloxane relative to all structural units constituting the polysiloxane is 40 mol% or more and 95 mol% or less.

7. The silicon-containing composition according to claim 1, wherein the polysiloxane further comprises a third structural unit represented by formula (3): 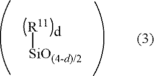
wherein R¹¹ is a substituted or unsubstituted aryl group having 6 to 20 carbon atoms, d is an integer of 1 to 3, and when d is 2 or more, a plurality of R¹¹s are the same or different from each other.

8. The silicon-containing composition according to claim 7, wherein a content of the third structural unit in the polysiloxane relative to all structural units constituting the polysiloxane is 1 mol% or more and 30 mol% or less.

9. The silicon-containing composition according to claim 1, which is suitable for forming a resist underlayer film.

10. A method for manufacturing a semiconductor substrate, the method comprising:
directly or indirectly applying the silicon-containing composition according to claim 1 to a substrate to form a silicon-containing film;
directly or indirectly applying a composition for forming a resist film to the silicon-containing film to form a resist film;
exposing the resist film to radiation; and
developing the exposed resist film to form a resist pattern.

11. The method according to claim 10, further comprising directly or indirectly forming an organic underlayer film on the substrate before forming the silicon-containing film.

12. The method according to claim 10, wherein the developing of the exposed resist film is conducted with an alkali developer.
